(19) United States
(12) Patent Application Publication
(10) Pub. No.: US 2020/0127152 A1
(43) Pub. Date: Apr. 23, 2020

(54) BIFACIAL SOLAR PANEL

(71) Applicant: 3M INNOVATIVE PROPERTIES COMPANY, St. Paul, MN (US)

(72) Inventor: Jiaying Ma, Cottage Grove, MN (US)

(21) Appl. No.: 16/566,448

(22) Filed: Sep. 10, 2019

Related U.S. Application Data
(60) Provisional application No. 62/731,184, filed on Sep. 14, 2018.

(51) Int. Cl. H01L 31/056; H01L 31/048; H01L 31/05

(52) U.S. Cl. CPC H01L 31/056; H01L 31/0504; H01L 31/0488

(57) ABSTRACT

A solar panel includes a solar cell and a partial reflector. The solar cell has a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, such that Q1≥Q2≥Q3. The partial reflector faces the solar cell and is configured to receive light transmitted by the solar cell and reflect at least a portion of the received light back toward the solar cell. The partial reflector reflects at least 50% of light in the second wavelength range and transmits at least 70% of light in each of the first and third wavelength ranges.

### BACKGROUND

Conventional photovoltaic (PV) modules, or solar panels, are monofacial (i.e., single-side), which means the electrical power generated by a conventional solar panel is a function of the sunlight captured on the front side of the solar panel only. A bifacial solar panel, on the other hand, converts light captured on both the front and back sides of the panel into electrical power. A bifacial solar panel captures incident light on the front side of the solar panel, and captures albedo light (i.e., the light reflected from a surface behind the panel) on the rear side of the solar panel. Depending on the reflectivity of the surface lying behind the bifacial solar panel, a bifacial solar panel can realize an increase in efficiency from 5% to 30% over a monofacial solar panel in the same location.

By using both sides of a solar cell to collect energy, bifacial solar panels enable the creation of very thin solar cells due to the balanced construction of the front and back sides of the solar cells. Creating thin solar cells (e.g., using less silicon and/or other materials in the cell construction) is important for cost reduction.

### SUMMARY

In some aspects of the present description, a solar panel including a solar cell and a partial reflector is described. The solar cell has a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, such that Q1≥Q2≥Q3. The partial reflector faces the solar cell and is configured to receive light transmitted (i.e., passed) by the solar cell and reflect at least a portion of the received light back toward the solar cell. The partial reflector reflects at least 50% of light in the second wavelength range and transmits at least 70% of light in each of the first and third wavelength ranges.

In some aspects of the present description, a solar panel is described, the solar panel including a first light-transmitting substrate, a second light-transmitting substrate, a bifacial solar cell disposed between the first light-transmitting substrate and the second light-transmitting substrate, and a multilayer optical film disposed on the second light-transmitting substrate and facing the bifacial solar cell. The first and second light-transmitting substrates are configured to substantially transmit light having wavelengths within the solar spectrum. The bifacial solar cell has a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, such that Q1≥Q2≥Q3. The first, second, and third wavelength ranges are defined within the solar spectrum. The multilayer optical film is configured to receive light transmitted by the solar cell and reflect at least a portion of the received light toward the bifacial solar cell, the multilayer optical film reflecting at least 50% of light in the second wavelength range and transmitting at least 70% of light in each of the first and third wavelength ranges.

In this application:

Terms such as “a”, “an” and “the” are not intended to refer to only a singular entity, but include the general class of which a specific example may be used for illustration. The terms “a”, “an”, and “the” are used interchangeably with the term “at least one”.

The phrase “at least one of followed by a list of two or more items refers to any one of the items in the list and any combination of two or more items in the list.

The term “light” refers to electromagnetic radiation, whether visible to the unaided human eye or not.

The term “polymer” refers to a macromolecular compound consisting essentially of one or more repeated monomeric units, or a mixture of macromolecular compounds that consist essentially of one or more like repeated monomeric units.

The terms “photovoltaic module”, “solar panel”, and “solar module” shall be synonymous for the purposes of this specification. A solar panel shall have at least one solar cell, but may have a plurality of solar cells. The terms “solar cell” and “photovoltaic cell” shall be synonymous for the purposes of this specification.

The term “plurality” means more than one.

All numerical ranges are inclusive of their endpoints and non-integral values between the endpoints unless otherwise stated.

### BRIEF DESCRIPTION OF THE DRAWINGS

FIG. 1A is a cross-sectional side view of a prior art bifacial solar cell in the prior art;

FIG. 1B is a graph charting silicon transmission spectra versus silicon thickness for a typical solar cell;

FIG. 2 is a cross-sectional side view of a bifacial solar panel with a partial reflector layer according to an embodiment of the present disclosure;

FIG. 3 is a cross-sectional side view of a bifacial solar panel with a partial reflector layer according to an embodiment of the present disclosure, illustrating how various wavelengths of light may be absorbed, transmitted, and/or reflected;

FIG. 4 is a plot illustrating the solar irradiation spectrum versus the quantum efficiency spectrum of a typical solar cell using monocrystalline silicon, defining a band of wavelengths reflected by a partial reflector according to an embodiment of the present disclosure;

FIG. 5 is a plot illustrating the transmission spectrum of a solar cell using doped silicon with anti-reflective coatings;

FIG. 6 is a perspective view of a partial reflector implemented as a multilayer optical film, according to an embodiment of the present disclosure;

FIG. 7 is a top view of a bifacial solar panel illustrating an array of bifacial solar cells and the tabbing ribbons connecting them, as seen in the prior art;

FIG. 8A is a top view of a pair of bifacial solar cells connected in series, with light redirecting film covering the tabbing ribbons, according to an embodiment of the present disclosure;

FIG. 8B. is a cross-sectional side view of a bifacial solar panel illustrating two series-connected bifacial solar cells, with light redirecting film covering the tabbing ribbons, according to an embodiment of the present disclosure;

FIG. 8C is a cross-sectional end view of a bifacial solar panel illustrating light redirecting film covering tabbing ribbons, according to an embodiment of the present disclosure;

FIG. 8D is a cross-sectional side view of a bifacial solar panel illustrating light redirecting film placed in the gaps between solar cells, according to an embodiment of the present disclosure;

FIG. 9 is a flowchart illustrating a method of manufacture used to create a highly-efficient bifacial solar panel, according to an embodiment of the present disclosure; and

FIG. 10 shows a transmission spectrum of the bifacial solar module, according to an embodiment of the present disclosure.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

According to some aspects of the present description, solar panels, or solar “modules,” incorporating the band reflecting layers described herein have been found to provide improved efficiency over conventional solar panels. A multilayer optical film can be created to act as a band reflecting layer, which may also be known as a band reflector or “partial reflector,” reflecting a first set of wavelengths while transmitting (i.e., allowing to pass) a second set of wavelengths. This partial reflector may be used to increase the efficiency of a bifacial solar panel. For example, a partial reflector may be created using the techniques described herein such that the partial reflector reflects a subset of wavelengths of light corresponding to an absorption band of a bifacial solar cell, while allowing all other wavelengths to be transmitted through the reflector.

A typical thickness for a bifacial solar cell today is 180 micrometers. Longer wavelengths of light may pass through thin solar cells, resulting in lower absorption and lower energy generated. For example, at 180 micrometers, light having a wavelength greater than around 900 nanometers is partially absorbed and partially transmitted through the solar cell. As this light is only partially absorbed by the solar cell and used to generate power, this transmission (or leaked light) translates into a loss of power (for example, a loss of 2%). As the thickness of solar cells is further reduced, more light will pass through the solar cell, increasing losses from leaked light. It is therefore desirable to recapture the light that transmits through a thin bifacial solar cell.

However, not all wavelengths of light passing through a thin solar cell can be used to generate electricity. For example, the absorption spectrum of a typical monocrystalline silicon solar cell ranges from approximately 350 nanometers to 1100 nanometers. Light with a wavelength longer than 1100 nanometers can be absorbed by the solar cell, but will not generate electricity. Instead, this absorbed light with a wavelength greater than 1100 nanometers will generate heat in the solar cell, and this heat will lower the efficiency of the solar cell. Therefore, it is desirable to create a partial reflector that can reflect transmitted light with wavelengths up to 1100 nanometers (to pass it back into the “back side” of the bifacial solar cell), but has a high transmission for light greater than 1100 nanometers (to prevent unnecessary and harmful heating of the solar cell).

Light of wavelengths in the lower end of the absorption spectrum of a solar cell (for example, light between 350 nanometers and 850 nanometers, in some embodiments) is strongly absorbed by the solar cell and need not be reflected by the partial reflector, as very little of this light, if any, passes through the solar cell. Therefore, an ideal partial reflector for a bifacial solar cell will reflect light of wavelengths corresponding to the longer wavelengths in the solar cell's absorption band (for example, between approximately 875 and 1100 nanometers, in one embodiment) and transmit all other wavelengths of light.

It should be noted that the wavelengths in the absorption band for a solar cell are defined by the material from which the solar cell is made, and the wavelengths presented throughout this discussion are intended as examples only, and not limiting in any way. That is, doping of silicon with materials such as boron and phosphorus allows the creation of N type or P type substrates, and can change the transmission and absorption characteristics of a solar panel.

In some embodiments, a solar panel including a solar cell and a partial reflector is described. The solar panel may be a bifacial solar panel including at least one bifacial solar cell disposed between a first light-transmitting substrate (for example, glass) and a second light-transmitting substrate. In some embodiments, an encapsulant made of a suitable, light-transparent, electrically non-conducting material (for example, ethylene vinyl acetate, or EVA) surrounds the bifacial solar cell(s), disposed between the first and second light-transmitting substrates and the solar cells. The first light-transmitting substrate represents a first or top side of the solar panel and is disposed on a side of the solar panel receiving incident light (e.g., sunlight). The second light-transmitting substrate represents a second or bottom side of the solar panel and is disposed on a side of the solar panel opposite to the first side. The second side of the solar panel receives albedo light (e.g., light reflected from the ground or surface behind the solar panel.)

The solar cell has a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, such that Q1≥Q2≥Q3. The partial reflector faces the solar cell and is configured to receive light transmitted by the solar cell and reflect at least a portion of the received light back toward the solar cell. The partial reflector reflects at least 50% of light in the second wavelength range and transmits at least 70% of light in each of the first and third wavelength ranges.

In some aspects of the present description, a solar panel is described, the solar panel including a first light-transmitting substrate, a second light-transmitting substrate, a bifacial solar cell disposed between the first light-transmitting substrate and the second light-transmitting substrate, and a multilayer optical film disposed on the second light-transmitting substrate and facing the bifacial solar cell. The first and second light-transmitting substrates are configured to substantially transmit light having wavelengths within the solar spectrum. The bifacial solar cell has a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, such that Q1≥Q2≥Q3. The first, second, and third wavelength ranges are defined within the solar spectrum. The multilayer optical film is configured to receive light transmitted by the solar cell and reflect at least a portion of the received light toward the bifacial solar cell, the multilayer optical film reflecting at least 50% of light in the second wavelength range and transmitting at least 70% of light in each of the first and third wavelength ranges.

The partial reflector may be disposed on the second light-transmitting substrate, and is designed to reflect light of a first set of wavelengths and to transmit light of a second set of wavelengths. Sunlight is received on the top side of the solar panel, passing through the first light-transmitting substrate, the encapsulant, and into the at least one solar cell where it is at least partially absorbed. Any wavelengths of light that are transmitted through the solar cell travel through the encapsulant toward the second light-transmitting substrate and partial reflector. In some embodiments, the partial reflector may be disposed between the encapsulant and the second light-transmitting substrate. In some embodiments, the partial reflector may be disposed on an external or outward-facing side of the second light-transmitting substrate.

As the light arrives at the partial reflector, the wavelengths of light for which the partial reflector has been designed to reflect are reflected back into the solar cell (into the “back side” of the bifacial solar cell), where they are at least partially absorbed, allowing additional electricity to be generated. Those wavelengths of light for which the partial reflector has been designed to transmit are passed through the partial reflector and outside of the solar panel. In some embodiments, the partial reflector may be designed to reflect the wavelengths of light corresponding to at least a subset of wavelengths of the absorption band of the bifacial solar cell(s).

This subset of wavelengths of the absorption band of the bifacial solar cells may be selected to reflect only that portion of the absorption band that is not strongly absorbed by the solar cells (i.e., longer wavelengths of light). This allows wavelengths of light that are strongly absorbed by the solar cells present in the albedo light entering the solar panel to pass through the second or bottom side of the solar panel, where they can be absorbed by the bifacial solar panels. For example, the partial reflector may be designed to reflect light between 875 nanometers and 1100 nanometers, or between 800 nanometers and 1200 nanometers, or between 900 and 1150 nanometers, or any appropriate range of wavelengths based on the absorption characteristics of the bifacial solar cells.

In some embodiments, the partial reflector may be a multilayer optical film, constructed of alternating layers of a first polymer type and a second polymer type, each polymer type exhibiting a different index of refraction from the other. By selecting the appropriate layer pairs with appropriate refractive indices, layer thickness, and/or the number of layer pairs, the multilayer optical film can be designed to transmit or reflect desired wavelengths of light.

By appropriate selection of the first polymer layers and the second polymer layers to create an “optical stack”, the partial reflector in the solar panels disclosed herein can be designed to reflect or transmit a desired bandwidth of light. Reflection is generated at each interface between polymer layers in an optical stack, where the alternating layers have refractive indices that are different, n1, and n2, respectively. Light that is not reflected at the interface of adjacent polymer layers typically passes through successive layers and is either absorbed in a subsequent polymer layer, reflected at a subsequent interface, or transmitted through the optical stack altogether.

Typically, the polymer layers of a given layer pair are selected to be substantially transparent to those light wavelengths at which reflectivity is desired. Light that is not reflected at a layer pair interface passes to the next layer pair interface where a portion of the light is reflected and unreflected light continues on, and so on. Increasing the number of polymer layers in the optical stack may provide more optical power. In this way, an optical stack with many layers is capable of generating a high degree of reflectivity.

For example, if the difference in refractive index (Δn) between the layer pairs is small, the optical stack may not achieve the desired reflectivity. However, by increasing the number of layer pairs, sufficient reflectivity may be achieved. In some embodiments of the present disclosure, the optical stack comprises at least 2 first polymer layers and at least 2 second polymer layers, at least 5 first polymer layers and at least 5 second polymer layers, at least 50 first polymer layers and at least 50 second polymer layers, at least 200 first polymer layers and at least 200 second polymer layers, at least 500 first polymer layers and at least 500 second polymer layers, or at least 1000 first polymer layers and at least 1000 second polymer layers. In general, at least a portion of the first polymer layers and at least a portion of the second polymer layers are in intimate contact.

By selecting polymers with specific indexes of refraction, as well as controlling the number of pairs of alternating polymer layers, it is possible to create a partial reflector which will reflect wavelengths of light in a first set of wavelengths (e.g., corresponding to the longer wavelengths in the absorption band of the solar cells), and transmit light in a second set of wavelengths (e.g., those wavelengths in the absorption band outside the first set of wavelengths.) In some embodiments, the partial reflector may be an inorganic optical stack.

In some embodiments, a method of manufacturing a bifacial solar panel includes the steps of creating a multilayer optical film by alternating layers of a first polymer type and a second polymer type, disposing at least one bifacial solar cell between a first light-transmitting substrate and a second light-transmitting substrate, and disposing the multilayer optical film on the second light-transmitting substrate. In some embodiments, the bifacial solar cell includes a front surface and a rear surface, the front surface facing the first light-transmitting substrate and representing an incident surface of a primary light (e.g., direct, incident light from the sun), the rear surface facing the second light-transmitting substrate and representing an incident surface of a secondary light (e.g., albedo light reflected from the ground or a mounting surface). In the multilayer optical film, the first polymer type and the second polymer type exhibit different indices of refraction, such that the multilayer optical film reflects light of a first set of wavelengths and transmits light of a second set of wavelengths.

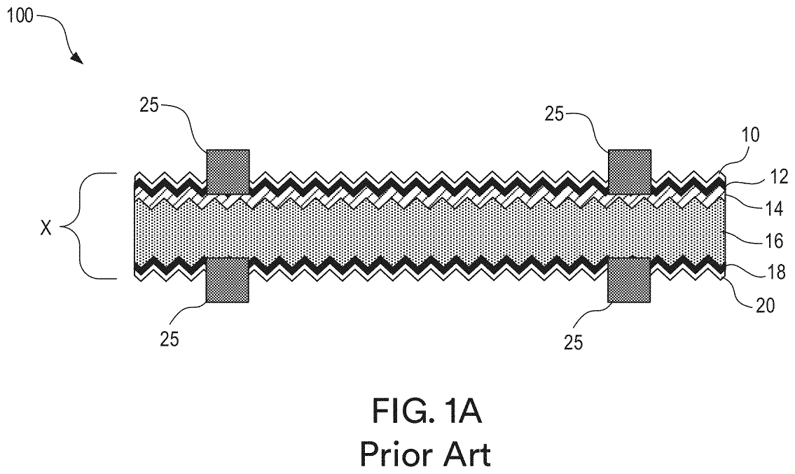

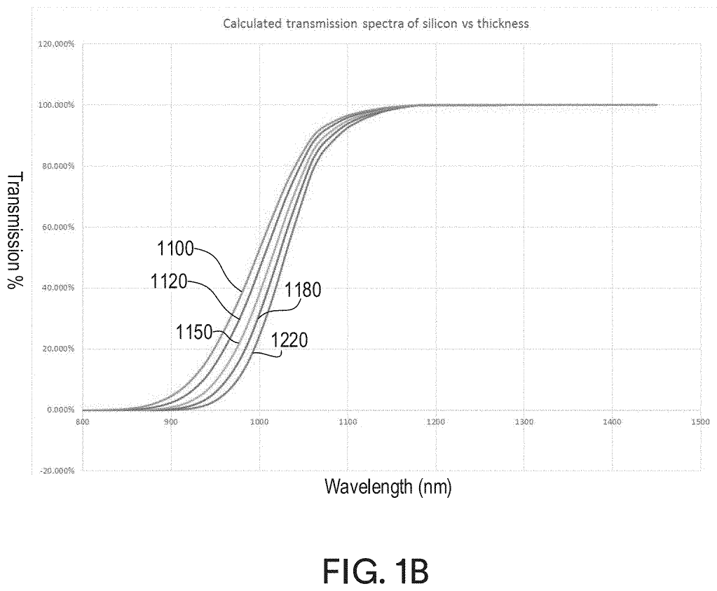

FIG. 1A is a cross-sectional view of a typical bifacial solar cell known in the art. In some embodiments, a bifacial solar cell 100 may include an antireflective coating/first front passivation layer 10 (e.g., a layer of SiNₓ), a second front passivation layer 12 (e.g., a layer of SiO₂), an emitter 14 (e.g., an n-type Si), a base layer 16 (e.g., a p-type Si), a second rear passivation layer 18 (e.g., a layer of SiO₂), and a first rear passivation layer 20 (e.g., a layer of SiNₓ). Electrodes 25 of a conductive material (e.g., silver) conduct electricity generated by the solar cell 100 to be used by an external load (not shown) or stored for future use. The bifacial solar cell 100 has an overall thickness X. For a typical bifacial solar cell in the prior art, the thickness is approximately 180 micrometers. The embodiment of FIG. 1A is an example of one type of bifacial solar cell in the prior art. Alternate materials and other layers may be used in the creation of a bifacial solar cell.

Although a bifacial solar cell of any appropriate thickness may be used, in some embodiments described herein, the thickness, X, of the bifacial solar cell may be less than 200 micrometers, 180 micrometers, 150 micrometers, 120 micrometers, or 100 micrometers. In each case, X may be greater than about 50 micrometers.

The amount of certain wavelengths of light that is absorbed and/or transmitted by solar cell 100 can be, in part, a function of the thickness X of the solar cell 100. A typical thickness used for a solar cell today is 180 micrometers. At this thickness, light of wavelengths greater than 900 nanometers may be largely transmitted through the silicon layer, resulting in a power loss which may be on the order of 5 to 10 watts when measured in a solar simulator. As this thickness is reduced even further with advances in the art (e.g., to 100 micrometers), additional wavelengths of light will be transmitted through the cell, resulting in additional power loss.

FIG. 1B is a graph showing the silicon transmission spectra for several solar cell thicknesses. Line 1220 represents the transmission spectrum as measured from a monocrystalline silicon solar cell of 220 micrometers thick. Line 1180 is the transmission spectrum as measured from a solar cell 180 micrometers thick. Line 1150 is the transmission spectrum as measured from a solar cell 150 micrometers thick. Line 1150 is the transmission spectrum as measured from a solar cell 150 micrometers thick. Line 1100 is the transmission spectrum as measured from a solar cell 100 micrometers thick.

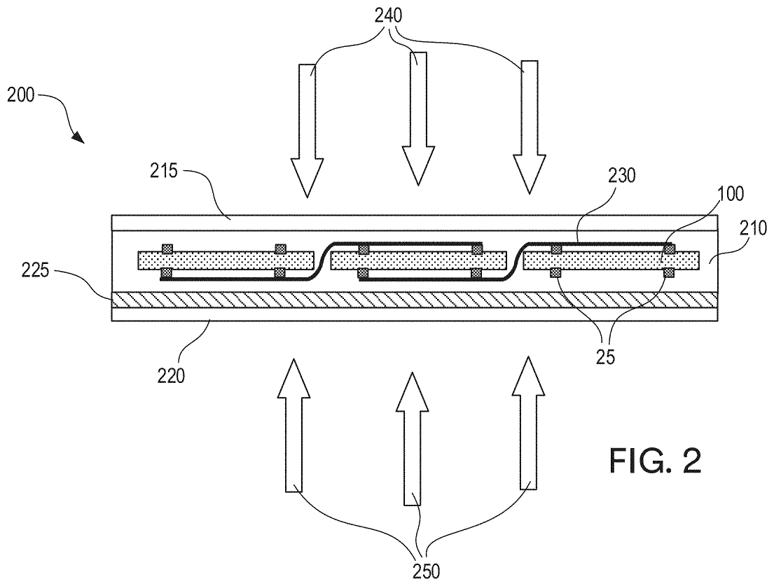

FIG. 2 is a cross-sectional view of a bifacial solar panel with a partial reflector layer, in accordance with an embodiment as described herein. A bifacial solar panel 200 includes a first light-transmitting substrate 215 on a first side of the solar panel 200, a second light-transmitting substrate 220 on a second side of the solar panel 200, at least one bifacial solar cell 100 disposed between the first light-transmitting substrate 215 and the second light-transmitting substrate 220, and a partial reflector 225. In some embodiments, the partial reflector 225 may be disposed between the second light-transmitting substrate 220 and the bifacial solar cell 100. In other embodiments, the partial reflector may be disposed on a first side of the second light-transmitting substrate 220 opposite a second side of the second light-transmitting substrate 220 facing the bifacial solar cell 100. The partial reflector may be designed to reflect light of a first set of wavelengths (e.g., those wavelengths corresponding to at least a portion of the useful absorption band of a solar cell) and to pass light of a second set of wavelengths (e.g., wavelengths outside of the useful absorption band of a solar cell).

The first light-transmitting substrate 215 and second light-transmitting substrate 220 may be comprised of any suitable material which allows light of at least certain wavelengths (e.g., wavelengths of a typical solar spectrum) to pass through. This material may include, but is not limited to, glass sheets, polymeric sheets, acrylic sheets, polymer fiber composites, and/or glass fiber composites. In some embodiments, the material used may not be completely transparent.

Each side of each bifacial solar cell 100 may have one or more electrodes 25, to conduct electricity generated by the bifacial solar cell 100. In some embodiments, one or more bifacial solar cells 100 are connected in series by one or more electrical connectors known as tabbing ribbons 230, which may be adhered to the solar cells 100 by a soldering process.

In some embodiments, the bifacial solar panel 200 may further include an encapsulant 210, the encapsulant substantially surrounding the at least one bifacial solar cell 100. In some embodiments, the encapsulant 210 may be such as generally described in U.S. Patent Application Publication No. 2008/0078445 (Patel et al.), the teachings of which are incorporated herein by reference.

The bifacial solar panel 200 captures incident light 240 on a first (i.e., front) side of the solar panel, and captures albedo light 250 (i.e., the light reflected from a surface behind the panel) on a second (i.e., rear) side of solar panel 200.

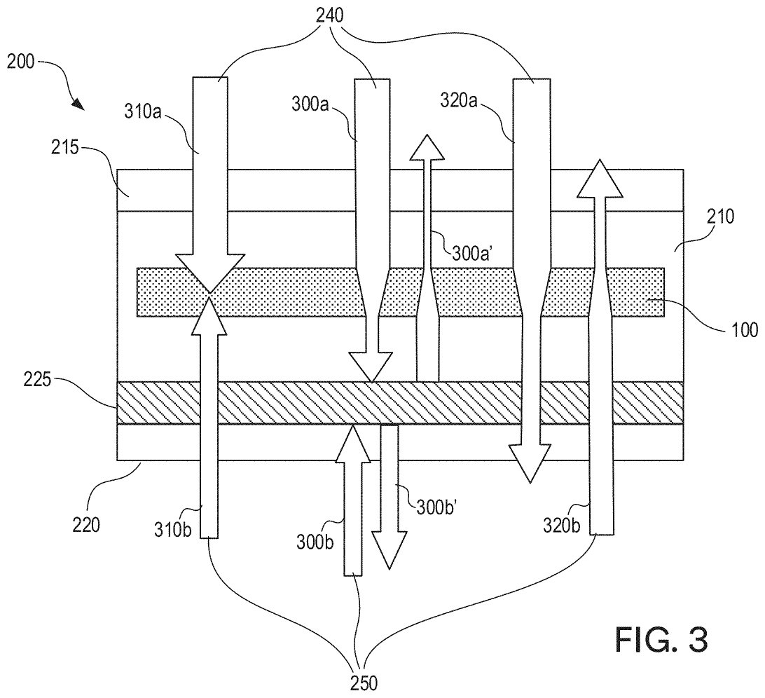

FIG. 3 is a cross-sectional view of a bifacial solar panel 200 with a partial reflector 225, illustrating how various wavelengths of light may be absorbed, transmitted, and/or reflected. FIG. 3 presents a simplified view of the bifacial solar panel 200 of FIG. 2, showing only a single bifacial solar cell 100 and omitting electrodes 25 and tabbing ribbons 230. Arrows show various wavelengths of light entering the solar panel 200 through both a first (front) light-transmitting substrate 215 and a second (rear) light-transmitting substrate. In some embodiments, solar cell 100 is surrounded by an encapsulant 210. In the embodiment shown in FIG. 3, a partial reflector 225 is shown disposed on the side of second light-transmitting substrate 220, but partial reflector 225 may also be disposed on the opposite side of second light-transmitting substrate 220 in some embodiments.

In FIG. 3, direct light 240 is depicted divided into three wavelength “bands”, 300a, 310a, and 320a, and albedo light 250 is depicted divided into three wavelength bands, 300b, 310b, and 320b. In an example embodiment, bands 310a and 310b correspond to wavelengths of light which are most likely to be strongly absorbed by solar cell 100 (i.e., wavelengths of light which are substantially absorbed and not transmitted through the solar cell). Wavelength bands 320a and 320b correspond to wavelengths of light which may be at least partially absorbed by solar cell 100, but which fall substantially outside of the absorption band of solar cell 100 (i.e., these wavelengths, when absorbed, contribute to heating of the solar cell 100 but are not converted into energy). Wavelength bands 300a and 300b correspond to wavelengths of light that are substantially within the absorption band of solar cell 100, but which are not strongly absorbed (i.e., only partially absorbed) by solar cell 100.

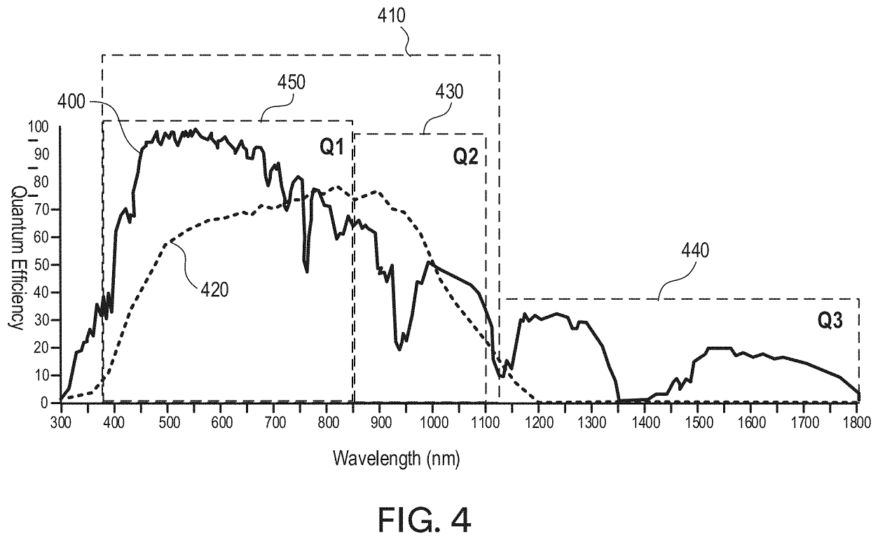

In some embodiments, partial reflector 225 is designed to reflect light of a first set of wavelengths (e.g., those wavelengths corresponding to wavelength bands 300a and 300b) and to pass light of a second set of wavelengths (e.g., those wavelengths corresponding to bands 310a, 310b, 320a, and 320b). In some embodiments, the wavelengths corresponding to wavelength bands 300a and 300b are those wavelengths between approximately 875 nanometers and approximately 1100 nanometers, the wavelengths corresponding to wavelength bands 310a and 310b are between approximately 350 nanometers and 875 nanometers, and the wavelengths corresponding to wavelength bands 320a and 320b are between approximately 1100 nanometers and 2500 nanometers. In other embodiments, the wavelengths corresponding to wavelength bands 300a and 300b are those wavelengths between approximately 800 nanometers and approximately 1200 nanometers, the wavelengths corresponding to wavelength bands 310a and 310b are between approximately 350 nanometers and 800 nanometers, and the wavelengths corresponding to wavelength bands 320a and 320b are between approximately 1200 nanometers and 2500 nanometers. The ranges of wavelengths in each wavelength band are defined by the properties of the material from which the solar cell 100 is constructed. That is, the wavelength ranges in each band 300a, 300b, 310a, 310b, 320a, and 320b will be defined by the absorption spectrum of the material of the solar cell 100, and the quantum efficiencies associated with wavelengths both in and out of the absorption spectrum, as follows:
Wavelength bands 310a and 310b will correspond to the wavelengths of light which are both within the absorption band of the solar cell 100 and strongly absorbed by the solar cell 100 (those wavelengths for which the solar panel exhibits a specific average quantum efficiency, Q1, as defined in FIG. 4);
Wavelength bands 300a and 300b will correspond to the wavelengths of light which are within the absorption band of the solar cell 100 but only partially absorbed (those wavelengths for which the solar panel exhibits a specific average quantum efficiency, Q2, as defined in FIG. 4); and
Wavelength bands 320a and 320b will correspond to the wavelengths of light which are outside the upper end of the absorption band of the solar cell 100 (those wavelengths for which the solar panel exhibits a specific average quantum efficiency, Q3, as defined in FIG. 4).

Returning to FIG. 3, the arrows representing wavelength bands 310a (incident light) and 310b (albedo light) are shown as entering the solar cell 100 but not transmitting through. This is because wavelengths in these wavelength bands are strongly absorbed by solar cell 100. Note that wavelength band 310b (the component from albedo light) passes through partial reflector 225.

The arrow representing wavelength band 300a (incident light) is shown as passing through solar cell 100 but being reflected back from partial reflector 225 to pass through the solar cell 100 on the return path. The 300a arrow is shown narrowing as it passes through solar cell 100, representing a partial absorption of the wavelengths of band 300a as it passes through solar cell 100. The arrow representing wavelength band 300b (albedo light) is shown reflecting off partial reflector 225, never having a chance to enter solar cell 100.

Finally, the arrows representing wavelength bands 320a (incident light) and 320b (albedo light) are shown passing through both solar cell 100 and partial reflector 225. These wavelength bands are at least partially absorbed by the solar cell 100, but, as they are outside of the absorption band of the solar cell 100, they will not be used to generate electricity. However, any light absorbed in bands 320a and 320b will contribute heat to the solar cell, which may reduce the efficiency of the solar cell. As these wavelength bands 320a and 320b may contribute to a reduction in efficiency in solar cell 100, it is best that these wavelengths pass through partial reflector 225, rather than be reflected into the solar cell.

FIG. 4 is a plot illustrating the solar irradiation spectrum versus the quantum efficiency spectrum of a typical solar cell using monocrystalline silicon. Line 400 represents the solar irradiation spectrum (or simply “solar spectrum”) which falls on a plane of a specific orientation and under specific atmospheric conditions, as defined by the American Society of Testing and Materials (ASTM) in the G173-03 Reference Spectra standard. Line 420 represents the quantum efficiency spectrum of a solar cell of monocrystalline silicon. The quantum efficiency spectrum can be thought of as the ratio of photons incident on the solar cell to the number of converted electrons output by the solar cell. As shown in FIG. 4, light of a wavelength of approximately 830 nanometers striking a solar cell of monocrystalline silicon will have a quantum efficiency of over 80% (i.e., approximately 80% of the light striking the solar cell at this wavelength will be converted into electricity). In another example, light of a wavelength greater than 1200 nanometers will provide zero percent efficiency (in other words, it will not generate electricity).

Box 410 defines the approximate range of light wavelengths which correspond to the absorption band of the solar cell (i.e., the range of wavelengths which will be “effective” in converting the incident photons into electrons). Box 440 defines the range of solar spectra wavelengths 400 above the absorption band 420 of the solar cell (and therefore cannot be used to generate electricity). Box 450 represents those wavelengths of the solar spectra 400 which fall within the absorption band 420 of the silicon solar cell and which are strongly absorbed by the solar cell. Box 430 represents those wavelengths of the solar spectra 400 which are not strongly absorbed by the solar cell, but which fall within the absorption band 420 of the silicon solar cell. It is this narrow band 430 which is the ideal band for reflecting back into the solar cell using a partial reflector (such as partial reflector 225, FIG. 3).

A solar cell will have a first average quantum efficiency Q1 when absorbing light within a first wavelength range, defined in FIG. 4 by box 450. The solar cell will have a second average quantum efficiency Q2 when absorbing light within a second wavelength range outside the first wavelength range, which is defined in FIG. 4 by box 430. The solar cell will have a third average quantum efficiency Q3 when absorbing light within a third wavelength range outside the first and second wavelength ranges, which is defined in FIG. 4 by box 440. The response of the solar cell is such that Q1≥Q2≥Q3.

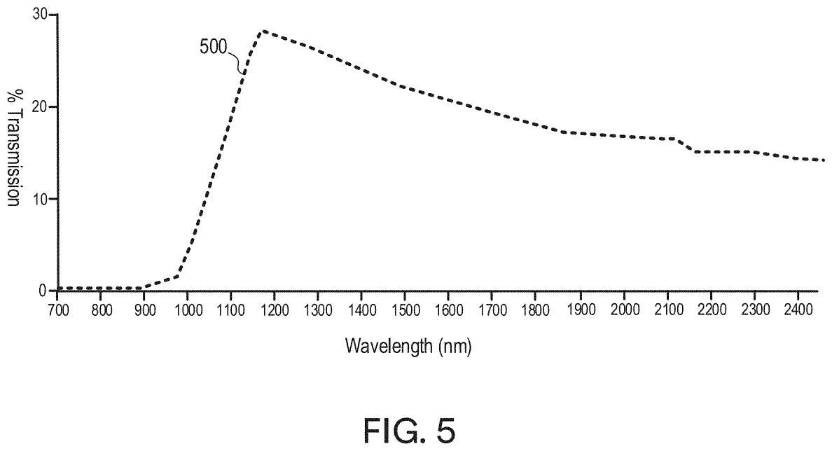

The examples discussed herein assume a solar cell constructed of monocrystalline silicon. Solar cells, however, are not made with pure silicon. Doping materials are added to pure silicon to generate N-type or P-type substrates. In addition, coatings (e.g., anti-reflective coatings) are added to one or more sides of the solar cell. These modifications generate solar cells exhibiting a transmission spectrum such as that shown by line 500 in FIG. 5. As seen in FIG. 5, the effects of doping and other modifications can increase the amount of absorption of wavelengths greater than 1100 nanometers. Thus, it is important to create a partial reflector which has a high transmission percentage for wavelengths above 1100 nanometers, to limit the amount of this ineffective light coming back into the solar cell. For the purposes of this specification, the term “ineffective light” shall mean those wavelengths of light which are absorbed by a solar cell, thus contributing heat to the system, but which cannot be used to generate electricity.

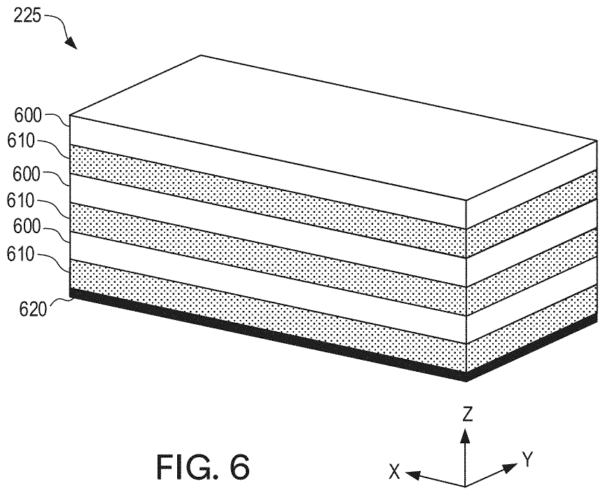

In some embodiments, the partial reflector described herein may be implemented as a multilayer optical film. FIG. 6 is a perspective view of a partial reflector 225 implemented as a multilayer optical film. In some embodiments, the multilayer optical film is an optical stack having alternating layers of a first polymer type 600 and a second polymer type 610. Layers 600 and 610 may each exhibit different refractive index characteristics so that some light is reflected at the interfaces between adjacent layers. The layers are sufficiently thin so that light reflected at a plurality of the interfaces undergoes constructive or destructive interference to give the partial reflector 225 the desired reflective or transmissive properties. For optical films designed to reflect light at ultraviolet, visible, or near-infrared wavelengths, each layer generally has an optical thickness (i.e., a physical thickness multiplied by refractive index) of less than about 1 micrometer. Thicker layers can, however, also be included, such as skin layers at the outer surfaces of the film, or protective boundary layers disposed within the film that separate packets of layers.

In some embodiments, the partial reflector 225 further includes an adhesive layer 620 on a first side of the multilayer optical film stack. Adhesive layer 620 enables the partial reflector 225 to be adhered to various components of the solar panel, such as the second light-transmitting substrate (e.g., 220, FIG. 2) in a manufacturing or application process.

In some embodiments, the adhesive layer 620 may be formulated to include an ultraviolet absorber to minimize ultraviolet radiation from the rear side of the solar panel (the side receiving albedo light) reaching the polymer-based partial reflector 225, which can cause degradation over time. A thermal-based adhesive is preferred as solar panels are typically made using a thermal lamination process. (Various adhesive candidates can be found in WO2018009465). EVA (ethylene vinyl acetate) is a commonly used encapsulate material for solar panels. Therefore, it is a preferred adhesive for use with the partial reflector 225, although any appropriate adhesive may be used. In some embodiments, the EVA may be cross-linked to achieve long term stability. A reactive system, such as a system using peroxide, may be used to cross-link EVA and provide enough adhesion to substrates, some of which may contain fluoropolymer surfaces. However, peroxide requires low temperature (<100-degree C.) extrusion, which limits line speed. Additionally, peroxide limits the shelf life of the adhesive and requires moisture barrier based packaging. Electron beam cross linking of EVA, on the other hand, requires no additional chemicals to the formulation. EVA can be extruded at high temperature and high speed, and then cross-linked by electron beam. Example of a formulation is: 99.2% Elvax3175 (DuPont Company, Wilmington, Del.) and 0.8% UV531 (Sartomer Americas, Exton, Pa.). The thickness of the adhesive can be determined based on surface texture of the second light-transmitting substrate (e.g., glass), between 10 micrometers to 50 micrometers.

The reflective and transmissive properties of partial reflector 225 are a function of the refractive indices of respective layers 600 and 610 (i.e., microlayers). Each layer can be characterized at least in localized positions in the partial reflector 225 by in-plane refractive indices nₓ, n_{y}, and a refractive index n_{z} associated with a thickness axis of the film. These indices represent the refractive index of the subject material for light polarized along mutually orthogonal X-, Y- and Z-axes, respectively (as shown in FIG. 6).

In practice, the refractive indices are controlled by judicious materials selection and processing conditions. The partial reflector 225 may be created by the co-extrusion of typically tens or hundreds of layers of two alternating polymer types 600 and 610, followed by optionally passing the multilayer extrudate through one or more multiplication dies, and then stretching or otherwise orienting the extrudate to form a final film. In some embodiments, the resulting partial reflector 225 is composed of typically tens or hundreds of individual layers whose thicknesses and refractive indices are tailored to provide one or more reflection bands in desired region(s) of the spectrum.

In order to achieve high reflectivity with a reasonable number of layers, adjacent layers of the partial reflector 225 preferably exhibit a difference in refractive index (Δnₓ) for light polarized along the X-axis (as defined in FIG. 6) of at least 0.05. In some embodiments, if the high reflectivity is desired for two orthogonal polarizations, then the adjacent layers also exhibit a difference in refractive index (Δn_{y}) for light polarized along the y-axis of at least 0.05. In other embodiments, the refractive index difference Δn_{y}, can be less than 0.05 or 0 to produce a multilayer stack that reflects normally incident light of one polarization state and transmits normally incident light of an orthogonal polarization state.

If desired, the refractive index difference (Δn_{z}) between adjacent layers for light polarized along the Z-axis can also be tailored to achieve desirable reflectivity properties for the p-polarization component of obliquely incident light. For ease of explanation, at any point of interest on a multilayer optical film, such as that used for partial reflector 225, the x-axis will be considered to be oriented within the plane of the film such that the magnitude of Δnₓ is a maximum. Hence, the magnitude of Δn_{y}, can be equal to or less than (but not greater than) the magnitude of Δnₓ. Furthermore, the selection of which material layer to begin with in calculating the differences Δnₓ, Δn_{y}, Δn_{z} is dictated by requiring that Δnₓ be non-negative. In other words, the refractive index differences between two layers forming an interface are Δₙⱼ=n₁ⱼ−n₂ⱼ, where j=X, Y, or Z and where the layer designations 1, 2 are chosen so that n₁ₓ≥n₂ₓ, i.e., Δnₓ≥0.

To maintain high reflectivity of p-polarized light at oblique angles of incidence, the Z-index mismatch Δn_{z} between layers can be controlled to be substantially less than the maximum in-plane refractive index difference Δnₓ, such that Δn_{z}≤0.5*Δnₓ. More preferably, Δn_{z}≤0.25*Δnₓ. A zero or near zero magnitude Z-index mismatch yields interfaces between layers whose reflectivity for p-polarized light is constant or near constant as a function of incidence angle. Furthermore, the Z-index mismatch Δn_{z} can be controlled to have the opposite polarity compared to the in-plane index difference Δnₓ, i.e. Δn_{z}<0. This condition yields interfaces whose reflectivity for p-polarized light increases with increasing angles of incidence, as is the case for S-polarized light.

Multilayer optical films have been described in, for example, U.S. Pat. No. 3,610,724 (Rogers); U.S. Pat. No. 3,711,176 (Alfrey, Jr. et al.), “Highly Reflective Thermoplastic Optical Bodies For Infrared, Visible or Ultraviolet Light’: U.S. Pat. No. 4,446,305 (Rogers et al.); U.S. Pat. No. 4,540,623 (Im et al.); U.S. Pat. No. 5,448,404 (Schrenk et al.); U.S. Pat. No. 5,882,774 (Jonza et al.) “Optical Film”; U.S. Pat. No. 6,045,894 (Jonza et al.) “Clear to Colored Security Film’: U.S. Pat. No. 6,531,230 (Weber et al.) “Color Shifting Film’: PCT Publication WO99/39224 (Ouderkirk et al.) “Infrared Interference Filter’; and US Patent Publication 2001/0022982 A1 (Neavin et al.), “Apparatus For Making Multilayer Optical Films’, all of which are incorporated herein by reference. In such polymeric multilayer optical films, polymer materials are used predominantly or exclusively in the makeup of the individual layers. Such films can be compatible with high-volume manufacturing processes, and may be made in large sheets and roll goods. The multilayer optical film used as partial reflector 225 can be formed by any useful combination of alternating polymer type layers. In many embodiments, at least one of the alternating polymer layers is birefringent and oriented. In some embodiments, one of the alternating polymer layer is birefringent and orientated and the other alternating polymer layer is isotropic. In one embodiment, the multilayer optical film is formed by alternating layers of a first polymer type including polyethylene terephthalate (PET) or copolymer of polyethylene terephthalate (coPET) and a second polymer type including poly(methyl methacrylate) (PMMA) or a copolymer of poly(methyl methacrylate) (coPMMA). In another embodiment, the multilayer optical film is formed by alternating layers of a first polymer type including polyethylene terephthalate and a second polymer type including a copolymer of poly(methyl methacrylate and ethyl acrylate). In another embodiment, the multilayer optical film is formed by alternating layers of a first polymer type including cyclohexanedimethanol (PETG) or a copolymer of cyclohexanedimethanol (coPETG) and second polymer type including polyethylene naphthalate (PEN) or a copolymer of polyethylene naphthalate (coPEN). In another embodiment, the multilayer optical film is formed by alternating layers of a first polymer type including polyethylene naphthalate or a copolymer of polyethylene naphthalate and a second polymer type including poly(methyl methacrylate) or a copolymer of poly(methyl methacrylate). Useful combinations of alternating polymer type layers are disclosed in U.S. Pat. No. 6,352,761, which is incorporated by reference herein.

In some embodiments, the multilayer optical film of FIG. 6 may be designed to reflect light of a first set of wavelengths and to transmit light of a second set of wavelengths. In some embodiments, the first set of wavelengths may correspond with at least a subset of wavelengths in the absorption band of the solar cell, typically those wavelengths in the absorption band of the solar cell which are not already strongly absorbed by the solar cell. As described herein, the first set of wavelengths may be the set of wavelengths between approximately 875 nanometers and 1100 nanometers, the set of wavelengths between approximately 800 nanometers and 1200 nanometers, or any other appropriate range of wavelengths corresponding to a portion of the absorption band of the solar cell. In some embodiments, the second set of wavelengths may correspond with at least a subset of the wavelengths that fall outside the absorption band of the solar cell. In some embodiments, the second set of wavelengths may be the wavelengths between approximately 350 nanometers and 875 nanometers and between approximately 1100 nanometers and 2500 nanometers. In other embodiments, the second set of wavelengths may be the wavelengths between approximately 350 nanometers and 800 nanometers and between approximately 1200 nanometers and 2500 nanometers. The second set of wavelengths may be any appropriate set of wavelengths that is substantially outside the absorption band of the solar cell, or may be any appropriate set of wavelengths that is substantially outside the portion of the absorption band of the solar cell that is not strongly absorbed by the solar cell.

In some embodiments, partial reflector 225 may have an average light reflection of at least 50 percent at an angle of incidence normal to the partial reflector 225 for the first set of wavelengths. In some embodiments, partial reflector 225 may have an average light transmission of at least 50 percent at an angle of incidence normal to the partial reflector 225 for the second set of wavelengths.

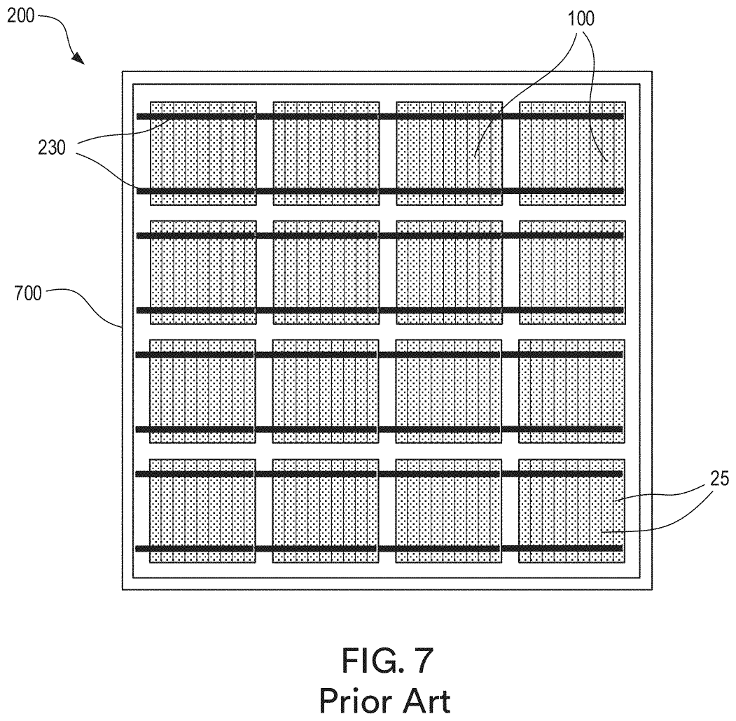

In some embodiments, the bifacial solar panel of FIG. 2 may include a plurality of bifacial solar cells connected in series by at least one conductor (i.e., tabbing ribbon), and at least one light redirecting film disposed on a surface of the tabbing ribbon, the surface of the at least one conductor positioned such that it receives incident light. FIG. 7 is a top view of a prior art bifacial solar panel illustrating an array of bifacial solar cells and the tabbing ribbons connecting them. In some embodiments, a bifacial solar panel 200 includes a plurality of bifacial solar cells 100 enclosed in a frame 700. Each bifacial solar cell 100 has a plurality of conductive lines (electrodes) 25 across both a top surface (typically substantially facing up toward direct, incident sunlight) and a bottom surface (typically substantially facing down toward albedo light reflected from a surface behind or beneath the solar panel). Connecting the bifacial solar cells 100 in series is a plurality of conductive bands or strips referred to as tabbing ribbons 230.

A drawback to the arrangement shown in FIG. 7 is that the tabbing ribbons 230 are opaque and are by necessity laid over the front and back surfaces of the solar cells 100 to make connections with the electrodes 25. The tabbing ribbons 230 therefore block sunlight from reaching the portion of the solar cells 100 directly beneath the tabbing ribbons 230, reducing the overall efficiency of the solar cells 100.

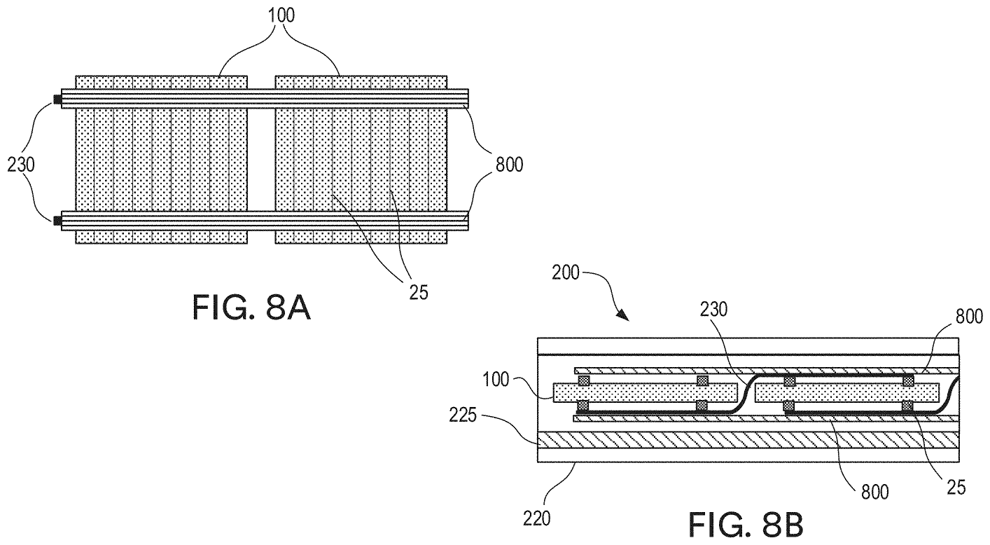

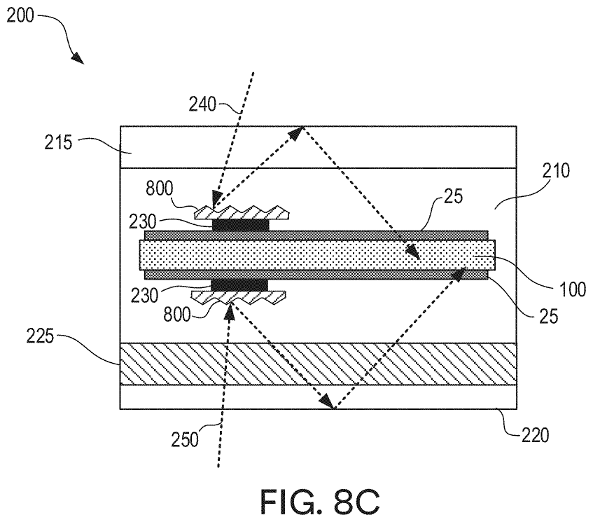

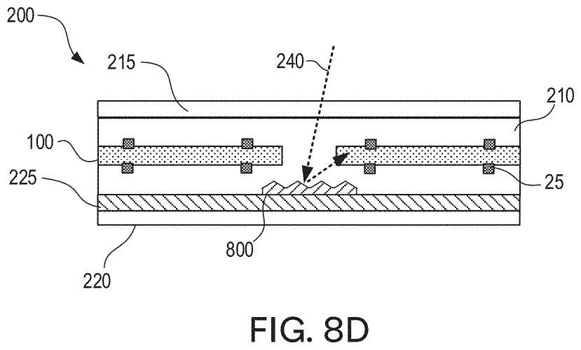

According to embodiments of the present disclosure, FIGS. 8A-8C illustrate the use of a light redirecting film placed over the tabbing ribbons 230 to reflect and redirect the light incident on the tabbing ribbons back into the solar panel 200 so that it may be recaptured by other areas of the solar cells 100. FIG. 8A is a top view of a pair of bifacial solar cells 100 connected in series by a pair of tabbing ribbons 230. Light redirecting film 800 is placed over the tabbing ribbons 230. FIG. 8B. is a side view of a bifacial solar panel 200 illustrating two series-connected bifacial solar cells 100, with light redirecting film 800 covering the tabbing ribbons 230. FIG. 8C is an end view of a bifacial solar panel 200 showing electrodes 25 extending across the width of the top and bottom sides of the solar cell 100, tabbing ribbons 230 resting on top of the electrodes 25, and light redirecting film 800 on top of the tabbing ribbons 230. Incident light ray 240 enters the solar panel 200, passing through the first light-transmitting substrate 215 and encapsulant 210, where it strikes a surface of the light redirecting film 800 and is reflected back to the inner surface of the front light-transmitting substrate 215. Ideally, the reflected light ray 240 strikes the inner surface of the front light-transmitting substrate 215 at an angle shallow enough to allow the ray to be reflected back into the solar cell 100 through total internal reflection (TIR) Similarly, an albedo light ray 250 enters the solar panel 200, passing through second light-transmitting substrate 220, partial reflector 225, and encapsulant 210, where it strikes light redirecting film 800 and is reflected through TIR into the solar cell 100. This assumes that albedo light ray 250 is of a wavelength that will be transmitted by partial reflector 225.

FIG. 8D is a side view of a bifacial solar panel 200 illustrating light redirecting film 800 placed in the gaps between solar cells 100. In some embodiments, the light redirecting film 800 is placed on a side of the partial reflector 225 facing the solar cells 100. In some embodiments, light redirecting film 800 is surrounded by and held in place by encapsulant 210. In some embodiments, light redirecting film 800 further includes an adhesive layer (not shown) to adhere the light redirecting film 800 to a substrate, such as partial reflector 225 or second light-transmitting substrate 220. In the embodiment shown in FIG. 8D, incident light 240 enters solar panel 200, passing through first light-transmitting substrate 215 and encapsulant 210, until it strikes a facet or surface of light redirecting film 800. After striking light redirecting film 800, light 240 is reflected up into the bottom side (albedo-facing side) of the solar cells 100, where it may be absorbed and converted into energy. In addition to reflecting light falling between adjacent solar cells 100 which may otherwise be lost through second light-transmitting substrate 220, the light redirecting film 800 may prevent or minimize the amount of ultraviolet radiation striking the partial reflector, increasing its life.

An example light redirecting film which may be used in the examples of FIGS. 8A-8D is generally described in U.S. Pat. No. 9,972,734 (Chen et al.), the disclosure of which is incorporated herein by reference.

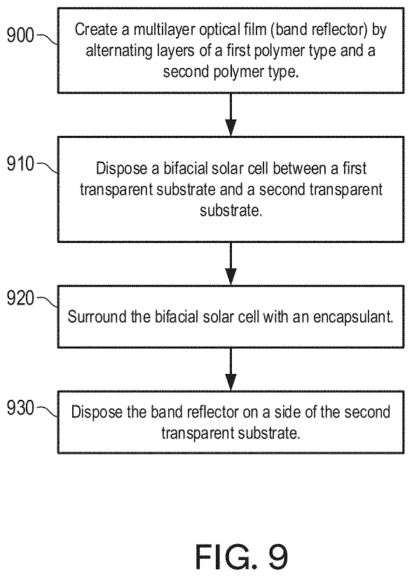

Finally, FIG. 9 is a flowchart illustrating a method of manufacture used to create a highly-efficient bifacial solar panel. In Step 900, a partial reflector designed to reflect a specific set of wavelengths, those wavelengths corresponding generally with at least a subset of wavelengths in the absorption band of the bifacial solar cell, is constructed as a multilayer optical film consisting of alternating layers of a first polymer type and a second polymer type. As previously discussed, the first polymer type and second polymer type are selected such that they each exhibit a different index of refraction. By carefully selecting materials with known indices of refraction, and by controlling the number of layers used to construct the multilayer optical film, the partial reflector can be designed to reflect a very specific range or set of wavelengths.

In Step 910, a bifacial solar cell is disposed between a first light-transmitting substrate and a second light-transmitting substrate. In Step 920, the solar cell is surrounded by an encapsulant, the encapsulant holding the solar cell suspended between the first light-transmitting substrate and the second light-transmitting substrate. In some embodiments, the encapsulant may take the form of an set of encapsulating films with sandwich the solar cell between substrates. Finally, in Step 930, the partial reflector created in step 900 is adhered, attached, or otherwise disposed on a side of the second light-transmitting substrate. In some embodiments, the partial reflector may be disposed on a first side of the second light-transmitting substrate (the side facing the bifacial solar cell). In other embodiments, the partial reflector may be disposed on a second side of the second light-transmitting substrate (the side opposite the bifacial solar cell).

It is important to note that the order of the steps in the manufacturing process of FIG. 9 may vary without diverging from the intent of the process. Also, some steps may be removed and other steps added. For example, an adhesive layer may be added to the partial reflector of Step 900 to allow it to be adhered to the second light-transmitting substrate during assembly.

### EXAMPLES

### Example 1: Bifacial Modules with 3M Prestige Partial Reflector Film Using Multilayer Optical Film

A bifacial solar module using a partial reflector film (3M Prestige Series Window Film) designed to reflect light between 875 nanometers and 1100 nanometers was constructed. One bifacial cell with thickness of 180 micrometers was used in the glass and glass construction with front and back ethylene vinyl acetate (EVA) layers as encapsulant layers. The partial reflector film was positioned between two back EVA layers in the experimental construction. The transmission spectra of the solar module

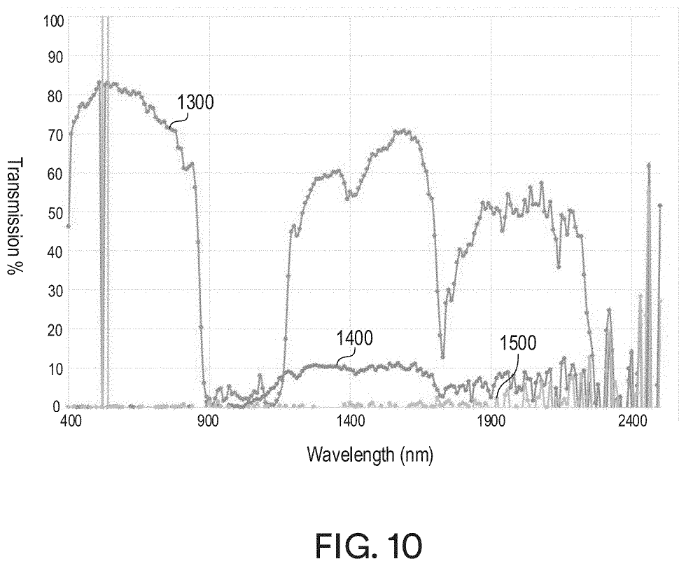

FIG. 10 shows the transmission spectrum of the bifacial solar module with partial reflector film 1400, partial reflector film transmission spectrum (free-standing film) 1300, and the transmission spectrum from a typical single-side module with white backsheet 1500.

With the single-sided module 1500, almost no light is transmitted through, indicating that even light greater than 1100 nanometers is absorbed by the cell. The free-standing partial reflector film 1300 reflects between 875 nanometers and 1100 nanometers, therefore having very low transmission in this region. The spectrum for the bifacial module with partial reflector 1400 transmits light greater than 1100 nanometers, but transmits very little to no light with a wavelength less than 1100 nanometers. The low transmission level (approximately 10%) shown for the bifacial module with partial reflector spectrum 1400 is due to absorption caused by cell dopants and/or anti-reflection coating.

### Example 2: Optimized Module Design for Bifacial Cells with Light Redirecting Film (Prophetic Example)

Due to balanced, double-sided construction, bifacial cells can be made thinner relative to a single-sided cell design, thereby reducing the amount of material needed and, accordingly, the cost of the solar cell. However, thin cells are fragile to handle during subsequent manufacturing process steps. The step of soldering thick tabbing ribbons to solar cells is typically where the highest amount of stress is introduced onto cells due to the significant difference in thermal properties between copper tabbing ribbons and silicon solar cells. The induced stress is directly proportional to tabbing ribbon thickness. With light redirecting films placed over the tabbing ribbons to minimize optical shadowing, tabbing ribbons can be made wider and thinner in order to minimize stress on solar cells.

With this approach, wider and thinner tabbing ribbons can be used, which are soldered to solar cells. Light redirecting film with about the same width as the tabbing ribbons (or slightly wider) is then applied over the tabbing ribbons. A partial reflector can then be applied behind the bifacial solar cells to reflect light that has “leaked” through the cells back into the cells through total internal reflection. It is possible to make the partial reflector with a prismatic shape to increase the optical path within the solar modules. Light redirecting film can be applied in the gaps between solar cells, as well. This use of light redirecting film maximizes the power output, and also blocks some harmful ultraviolet light from falling on the partial reflector, prolonging the life of the partial reflector.

### Example 3: Optimized Module Design for Bifacial Cells with Conductive Adhesive (Prophetic Example)

Similar to Example 2, except conductive adhesive is used to replace soldering for further stress reduction when attaching tabbing ribbons. Conductive adhesives, such as conductive film (CF) provided by Hitachi and solar cell conductive film (SCF) provided by Sony, require a lower bonding temperature (approximately 180 degrees Celsius) compared to soldering (approximately 250 degrees Celsius for lead-free soldering and 210 degrees Celsius for lead soldering). The wider and thinner ribbons enabled by the use of light-redirecting films will help reduce the stress level during manufacturing. This approach enables ultra-thin solar cells, such as 100 micrometer thick bifacial cells.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially equal” is not otherwise clear to one of ordinary skill in the art in the context in which it is used and described in the present description, “substantially equal” will mean about equal where about is as described above. If the use of “substantially parallel” is not otherwise clear to one of ordinary skill in the art in the context in which it is used and described in the present description, “substantially parallel” will mean within 30 degrees of parallel. Directions or surfaces described as substantially parallel to one another may, in some embodiments, be within 20 degrees, or within 10 degrees of parallel, or may be parallel or nominally parallel. If the use of “substantially aligned” is not otherwise clear to one of ordinary skill in the art in the context in which it is used and described in the present description, “substantially aligned” will mean aligned to within 20% of a width of the objects being aligned. Objects described as substantially aligned may, in some embodiments, be aligned to within 10% or to within 5% of a width of the objects being aligned.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed:

1. A solar panel comprising:
a solar cell having first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, Q1≥Q2≥Q3; and
a partial reflector facing the solar cell and configured to receive light transmitted by the solar cell and reflect at least a portion of the received light toward the solar cell, the partial reflector reflecting at least 50% of light in the second wavelength range and transmitting at least 70% of light in each of the first and third wavelength ranges.

2. The solar panel of claim 1, wherein the second wavelength range is disposed between the first and third wavelength ranges.

3. The solar panel of claim 1, wherein the solar cell is a bifacial solar cell.

4. The solar panel of claim 1, wherein the partial reflector is a multilayer optical film.

5. The solar panel of claim 4, wherein the multilayer optical film comprises an optical stack having alternating layers of a first polymer type and a second polymer type, the first polymer type and the second polymer type having different indices of refraction.

6. The solar panel of claim 2, wherein the second wavelength range comprises wavelengths between 875 nanometers and 1100 nanometers.

7. The solar panel of claim 2, wherein the second wavelength range comprises wavelengths between 800 nanometers and 1200 nanometers.

8. The solar panel of claim 2, wherein the second wavelength range corresponds with at least a subset of wavelengths in an absorption band of the solar cell.

9. The solar panel of claim 1, wherein a thickness of the solar cell is less than 180 micrometers.

10. The solar panel of claim 1, wherein a thickness of the solar cell is less than 150 micrometers.

11. A solar panel, comprising:
a first light-transmitting substrate configured to substantially transmit light having wavelengths within a solar spectrum;
a second light-transmitting substrate configured to substantially transmit light having wavelengths within the solar spectrum;
a bifacial solar cell disposed between the first light-transmitting substrate and the second light-transmitting substrate, the bifacial solar cell having a first average quantum efficiency Q1 when absorbing light within a first wavelength range, a second average quantum efficiency Q2 when absorbing light within a second wavelength range outside the first wavelength range, and a third average quantum efficiency Q3 when absorbing light within a third wavelength range outside the first and second wavelength ranges, Q1≥Q2≥Q3, the first, second, and third wavelength ranges within the solar spectrum; and
a multilayer optical film disposed on the second light-transmitting substrate and facing the bifacial solar cell, configured to receive light transmitted by the bifacial solar cell and reflect at least a portion of the received light toward the bifacial solar cell, the multilayer optical film reflecting at least 50% of light in the second wavelength range and transmitting at least 70% of light in each of the first and third wavelength ranges.

12. The solar panel of claim 11, wherein the first, second, and third wavelength ranges are adjacent and non-overlapping, the second wavelength range being disposed between the first and third wavelength ranges.

13. The solar panel of claim 11, wherein the multilayer optical film comprises alternating layers of a first polymer type and a second polymer type, the first polymer type and the second polymer type having different indices of refraction.

14. The solar panel of claim 11, wherein the second wavelength range comprises wavelengths between 875 nanometers and 1100 nanometers.

15. The solar panel of claim 11, wherein the second wavelength range comprises wavelengths between 800 nanometers and 1200 nanometers.

16. The solar panel of claim 11, wherein the second wavelength range corresponds with at least a subset of wavelengths in an absorption band of the bifacial solar cell.

17. The solar panel of claim 11, further comprising:
a plurality of bifacial solar cells;
at least one conductor connecting at least a subset of the plurality of bifacial solar cells in series; and
at least one light redirecting film disposed on a surface of the at least one conductor, the surface of the at least one conductor positioned such that it receives incident light.

18. The solar panel of claim 11, further comprising:
two bifacial solar cells separated by a gap; and
at least one light redirecting film, the light redirecting film disposed on the multilayer optical film and positioned to reflect light which passes through at least a portion of the gap.

19. The solar panel of claim 11, wherein the multilayer optical film comprises an adhesive layer.

20. The solar panel of claim 19, wherein the adhesive layer comprises an ultraviolet light absorbing material.
